(19) United States
(12) Patent Application Publication
(10) Pub. No.: US 2012/0081165 A1
(43) Pub. Date: Apr. 5, 2012

(54) HIGH VOLTAGE TOLERATIVE DRIVER

(75) Inventors: Jiann-Tseng HUANG, Hsinchu (TW); Sung-Chieh LIN, Zhubei (TW); Kuoyuan HSU, San Jose, CA (US); Po-Hung CHEN, Taipei City (TW)

(73) Assignee: TAIWAN SEMICONDUCTOR MANUFACTURING CO., LTD., Hsin-Chu (TW)

(21) Appl. No.: 12/894,210

(22) Filed: Sep. 30, 2010

(51) Int. Cl. H03L 5/00; H01H 37/76; H01L 25/00

(52) U.S. Cl. 327/306; 327/566; 327/525

(57) ABSTRACT

A high voltage tolerative inverter circuit includes a first PMOS transistor with a source connected to VDDQ and drain connected to a first node; a second PMOS transistor with a source connected to the first node and a drain connected to an output; a first NMOS transistor with a source connected to VSS and a drain connected to a second node; a second NMOS transistor with a source connected to the second node and a drain connected to the output. A gate of the first PMOS transistor is controlled by a first signal having a voltage swing between VDDQ and VSS. A gate of the first NMOS transistor and the second PMOS transistor are controlled by a second signal having a voltage swing between VDD and VSS. VDD is lower than VDDQ. A gate of the second NMOS transistor is biased with a first voltage greater than VSS.

### TECHNICAL FIELD

The present disclosure relates to integrated circuit (IC) designs, and more particularly to drive circuit designs.

### BACKGROUND

Semiconductor field-effect transistors use silicon dioxide, or “oxide”, as a gate oxide material. For a given thickness, the oxide can only tolerate a certain amount of voltage stress. An oxide layer can break down instantaneously at 0.8-1.1 V per angstrom (Å) of thickness. Excessive voltage even far lower than the above break down voltage can degrade gate oxide integrity (GOI), and lead to eventual failure.

In modern semiconductor integrated circuits (ICs) there are always situations where gate oxides may be subjected to excessive voltages. For instance, in Flash memory devices, program or erase may require a voltage as high as 18 V. In electrical fuse circuits, programming may also require a voltage as high as 2.75 V while the normal operating voltage is only 1.2V. These high voltages will particularly put stress on driver devices that deliver such high voltages. Complimentary metal-oxide-semiconductor (CMOS) inverters are most commonly used for such driver devices.

The conventional CMOS inverter includes a P-type metal-oxide-semiconductor (PMOS) transistor connected to a high voltage power supply, VDDQ, and an N-type metal-oxide-semiconductor (NMOS) transistor connected to a ground, VSS. Gates of both the PMOS transistor and the NMOS transistor are connected together to an input terminal, IN, of the inverter. Drains of both the PMOS transistor and the NMOS transistor are connected together to an output terminal, OUT, of the inverter. Substrates of the PMOS transistor and the NMOS transistor are connected to VDDQ and VSS, respectively. When the input terminal IN is supplied with the VDDQ voltage, the gate oxide of the NMOS transistor will be subjected to VDDQ, while the gate oxide of the PMOS transistor is not stressed. On the other hand, when the input terminal IN is supplied with VSS, the gate oxide of the PMOS transistor will be subjected to the VDDQ voltage. Empirically, the gate oxide of the NMOS transistor is much more susceptible to the voltage stress than the PMOS transistor, as judged by the time-dependent dielectric breakdown (TDDB) metric. Under the same stress voltage, the gate oxide of the NMOS transistor is about 55 times weaker than that of the PMOS transistor. The low NMOS gate oxide robustness reduces the overall high voltage tolerance of the driver.

### BRIEF DESCRIPTION OF THE DRAWINGS

The accompanying drawings illustrate preferred embodiments, as well as other information pertinent to the disclosure, in which:

FIG. 1 is a schematic diagram illustrating a high voltage tolerative CMOS inverter, and

FIGS. 2A and 2B illustrate biasing conditions for the inverter of FIG. 1 when the output is low and high, respectively;

FIG. 3 is a schematic diagram illustrating a high voltage tolerative CMOS inverter in accordance with an embodiment, and

FIGS. 4A and 4B illustrate biasing conditions for the inverter of FIG. 3 when the output is low and high, respectively;

FIG. 5 is a schematic diagram illustrating a word-line driver employing the high voltage tolerative CMOS inverter of FIG. 3;

FIG. 6 is a schematic diagram illustrating a fuse module employing the high voltage tolerative CMOS inverter of FIG. 3; and

FIG. 7 illustrates an embodiment of a method of operating a high voltage tolerative CMOS inverter.

### DETAILED DESCRIPTION

This description of the exemplary embodiments is intended to be read in connection with the accompanying drawings, which are to be considered part of the entire written description. Terms concerning electrical attachments, coupling and the like, such as “connected” and “interconnected,” refer to a relationship wherein structures communicate with one another either directly or indirectly through intervening structures, unless expressly described otherwise.

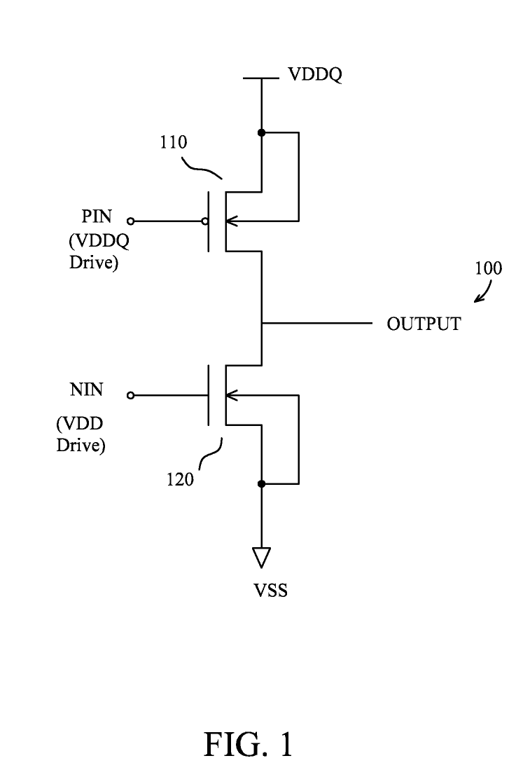

FIG. 1 is a schematic diagram illustrating a high voltage tolerative CMOS inverter of the type disclosed in commonly assigned co-pending U.S. patent application Ser. No. 12/057,585, which corresponds to U.S. Patent Application Publication No. 2009/0243705, the entirety of which is hereby incorporated by reference herein. Like the conventional CMOS inverter, the CMOS inverter 100 has a PMOS transistor 110 and a NMOS transistor 120 serially connected between VDDQ and the VSS supplies with the drains commonly connected to the output terminal OUTPUT. However, unlike the conventional CMOS inverter, the gates of the PMOS transistor 110 and the NMOS transistor 120 of FIG. 1 are not connected together to a single input terminal. Rather, the gates of the transistors are separately biased. The input to the PMOS 110 swings between VDDQ and VSS, but the input to NMOS 120 swings between another high voltage supply VDD, which is lower than VDDQ, and VSS. When a high voltage output at terminal OUTPUT is desired, both the input terminals, PIN and NIN will be supplied with VSS. The PMOS transistor 110 will be turned on to pull the output terminal OUTPUT up to VDDQ, and the NMOS transistor 120 will be turned off. When a low voltage output is desired at the output terminal OUTPUT, the input terminal PIN of the PMOS 110 transistor will be applied with VDDQ, which turns off the PMOS transistor 110, and the gate of the NMOS transistor 120 will be supplied with the VDD driving voltage, which turns on the NMOS transistor 120 and pulls the output terminal OUTPUT to VSS. In this way, the gate of the NMOS transistor 120 is not subjected to the VDDQ voltage, which can cause damage to the gate oxide thereof. Even though the gate of the PMOS transistor 110 is still subjected to VDDQ when the PIN is at VSS, the PMOS gate oxide is much more robust than the NMOS gate oxide. Therefore, the overall high voltage tolerance of the inverter 100 is improved.

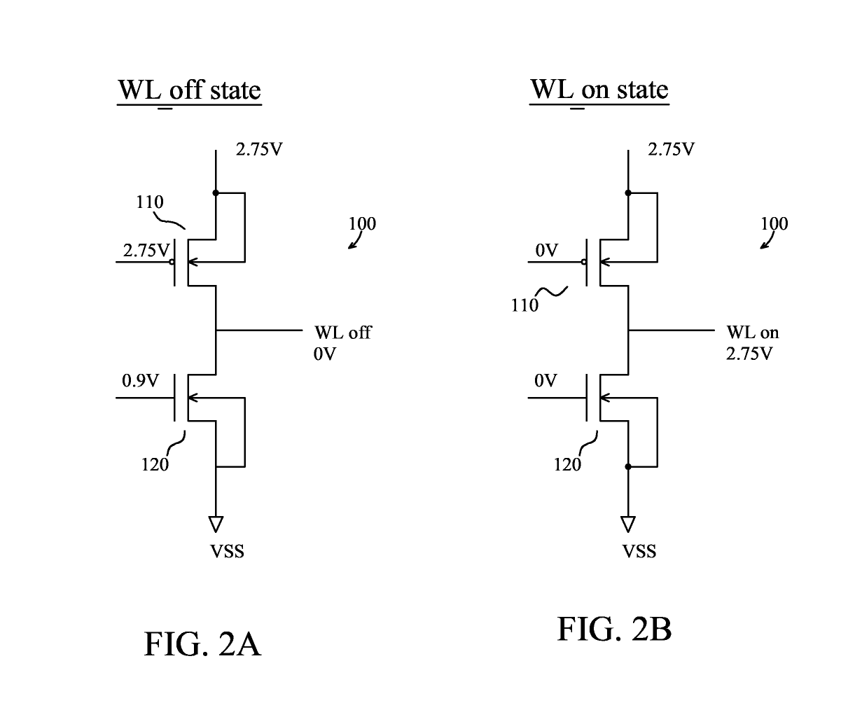

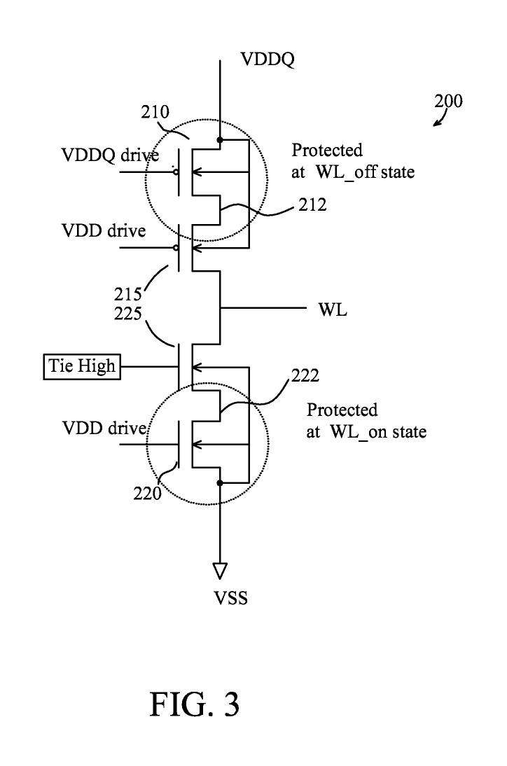

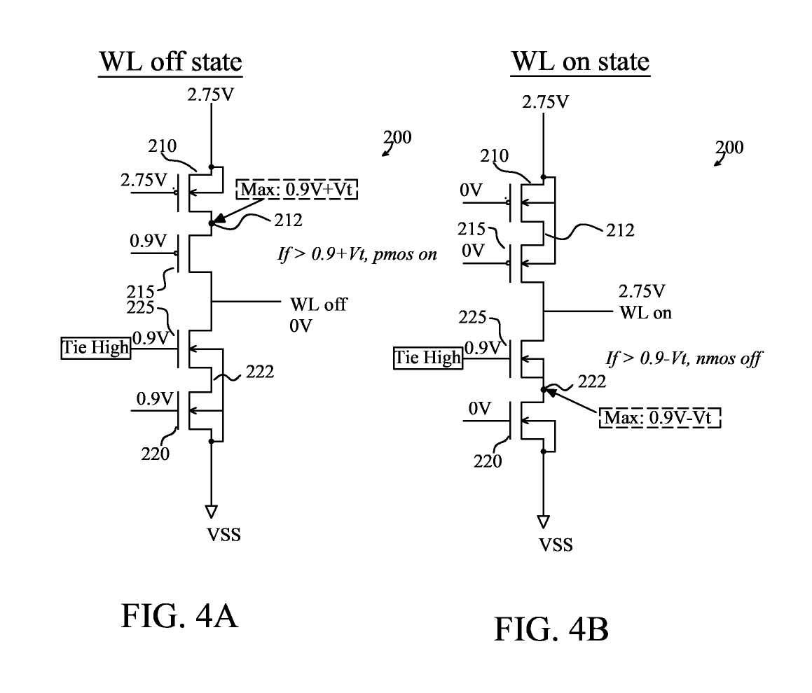

In high density devices, such as electrical fuses, due to the aforementioned GOI issue, the stress time is restricted. This limits the program time and memory size. The driver 100 operates well to relieve the GOI issue and thus increases the programming operating time to allow VDDQ (e.g., 2.75V) to be applied to higher memory size. However, as memory densities increase with reduced transistor sizes (e.g., 40 nm and below), the driver 100 may suffer reliability issues in both the word line “on” (PMOS 110 reliability issue) and the standby mode or word line “off” (NMOS 120 reliability issue), as shown in FIGS. 2A and 2B, respectively. For example, for deep sub-micron devices (e.g., 40 nm and smaller), the 2.75V gate-to-drain voltage for PMOS 110 under the conditions of FIG. 2A can cause reliability problems. Likewise, the 2.75V gate-to-drain voltage for NMOS 120 under the conditions of FIG. 2B can cause reliability problems, particularly for the less tolerant NMOS transistor. A modified CMOS inverter based driver design 200 is described in connection with FIGS. 3, 4 and 4A that can reduce these reliability stress issues when a high voltage is supplied, regardless of whether in the program mode or in standby mode.

FIG. 3 shows an embodiment of a high voltage tolerative driver 200 incorporating a CMOS inverter. In series from supply node VSS to supply node VDDQ, the driver 200 includes: a first NMOS transistor 220 having its source connected to VSS and drain connected to node 222; a second NMOS transistor 225 having its source connected to node 222 and its drain connected to the output node (labeled WL for convenience); a first PMOS transistor 210 having its source connected to supply node VDDQ and its drain connected to node 212; and a second PMOS transistor 215 having its drain connected to node 212 and its source connected to the output node. The gate of first PMOS transistor 210 is driven with a signal that swings between VSS and high voltage supply VDDQ, and the gate of first NMOS transistor 220 is driven with a signal that swings between VSS and voltage supply VDD, which is lower than VDDQ. It should be understood that the transitions of these two drive signals are synchronized, i.e., simultaneous and in the same direction. The gate of second PMOS transistor 215 is driven with a signal that swings between VSS and VDD, and the gate of the second NMOS transistor 225 is tied high to a constant voltage such that the NMOS transistor 225 is on. By way of example, this constant voltage may be VDD.

The driver 200 makes use of two principles to protect PMOS 210 an NMOS 270 from GOI. First, the input to PMOS and NMOS transistors 210, 220 is separated. Second, a stack of PMOS and NMOS transistors is used to reduce the voltage across each MOS to enhance device reliability under high voltage stresses that appear when a device is off. This point is illustrated in more detail with respect to FIGS. 4A and 4B.

FIGS. 4A and 4B illustrate the biasing conditions when word line is in the off state (i.e., output of the inverter is low (VSS)) and those conditions when the word line is in the on state (i.e., output of the inverter is high (VDDQ)), respectively. In this example, VDDQ is set to 2.75 V and VDD is set to 0.9 V. By way of example, only 0.9V is the VDD value for certain 45 nm general purpose logic circuits, and it should be understood that other VDD values can be adopted consistent with the selected fabrication process and generation. In the off state (FIG. 4A), the PMOS 210 is set to VDDQ, turning PMOS 210 off, and NMOS 220 is set to VDD, turning NMOS 220 on. NMOS 225 is also tied to a high voltage (e.g., VDD) and is on. PMOS 215 is driven with voltage VDD and is off. In the illustrated embodiment, PMOS 215 and NMOS 220 are coupled to the same drive signal. The circuit and these biasing conditions protect PMOS 210 from excessive voltage stress when the output is low (0V). The voltage at node 212 reaches a maximum of 0.9V plus the threshold voltage (Vt) of the PMOS transistor (i.e., 0.9V+Vt) since the second PMOS 215 would be on if the voltage were greater than 0.9V+Vt. The maximum gate-to-drain voltage (V_{gd}) experienced by first PMOS transistor 210 is 2.75V−(0.9V+Vt), i.e., 1.65V−Vt, which is less than VDDQ. The PMOS transistor is robust enough to withstand this voltage. In contrast, with the inverter of FIG. 1, the gate-to-drain voltage of the PMOS transistor 110 is 2.75V when the output WL is low (0V).

In the on state (FIG. 4B), PMOS 210 is set to 0V, turning PMOS 210 on, and NMOS 220 is set to 0V, which turns NMOS 220 off. NMOS 225 is again tied to a high voltage (e.g., VDD) such that it is on. PMOS 215 is driven with voltage 0V and is on. The circuit and these biasing conditions protect NMOS 220 from excessive voltage stress. The voltage at node 222 reaches a maximum of 0.9V minus the threshold voltage (Vt) of the NMOS transistors (i.e., 0.9V−Vt) since the second NMOS 225 would be off (Vgs<Vt) if the voltage at node 222 were any greater than 0.9V−Vt. NMOS 225 is on so as to reduce the voltage at node 222, thus protecting first NMOS transistor 220. As such, the maximum gate-to-drain voltage (V_{gd}) experienced by first NMOS transistor 220 is 0.9V−Vt, which is less than VDDQ. In contrast, with the inverter of FIG. 1, the gate-to-drain voltage of the NMOS transistor 120 is the full 2.75V when the output WL is high (2.75V). The gate-to-drain voltage (Vgd) of NMOS 225 is 1.65V under these biasing conditions, but the maximum accumulative time when VDDQ=2.75V is typically less than 1 sec in fuse programming specifications so this moderate stress is not an issue.

Table I below records a set of time-dependent dielectric breakdown (TDDB) data on both NMOS and PMOS gate oxides for the driver 100 of FIG. 2 and the driver 200 of FIG. 3. The selected process generation was the 40 nm logic generation and the temperature was set at 125° C. with 0.1% device failure rate in the set lifetime. The table includes information on the size of the device, the gate, drain, source and substrate voltages, the stress time and the lifetime. “Stress time” represents the real time that the transistors are stressed. For example, 0.64 ms may be the actual program time for a fuse macro. When fuse is being programmed, the output of the buffer is 2.75V. The stress time of NMOS is only 0.64 ms. When the fuse is not being programmed, the output of buffer is 0V. The stress time of PMOS is 1000 ms (i.e., one second). “Lifetime” means the time at which 0.1% device failure rate occurs under the forced voltage bias, as determined by TDDB calculations from the simulation.

TABLE I

| | | Area | | | | | | Stress Time | Lifetime |
|---|---|---|---|---|---|---|---|---|---|
| | | (μm2) | State | Vg | Vd | Vs | Vb | (ms) | (ms) |
| Driver | PMOS | 460.8 | Off | 2.75 | 0 | 2.75 | 2.75 | 1000 | 1.44 |
| 100 | 110 | | | | | | | | |
| | NMOS | 230.4 | Off | 0 | 2.75 | 0 | 0 | 0.64 | 0.08 |
| | 120 | | | | | | | | |
| Driver | PMOS | 460.8 | Off | 2.75 | 1.22 | 2.75 | 2.75 | 1000 | 4552 |
| 200 | 210 | | | | | | | | |
| | NMOS | 230.4 | Off | 0 | 0.75 | 0 | 0 | 0.64 | very |
| | 220 | | | | | | | | safe |

As shown in the table, the use of separate drive signals and stacked devices in the driver 200 reduces the oxide stress on the off-state NMOS and off-state PMOS transistors when a high voltage supply (VDDQ) is used.

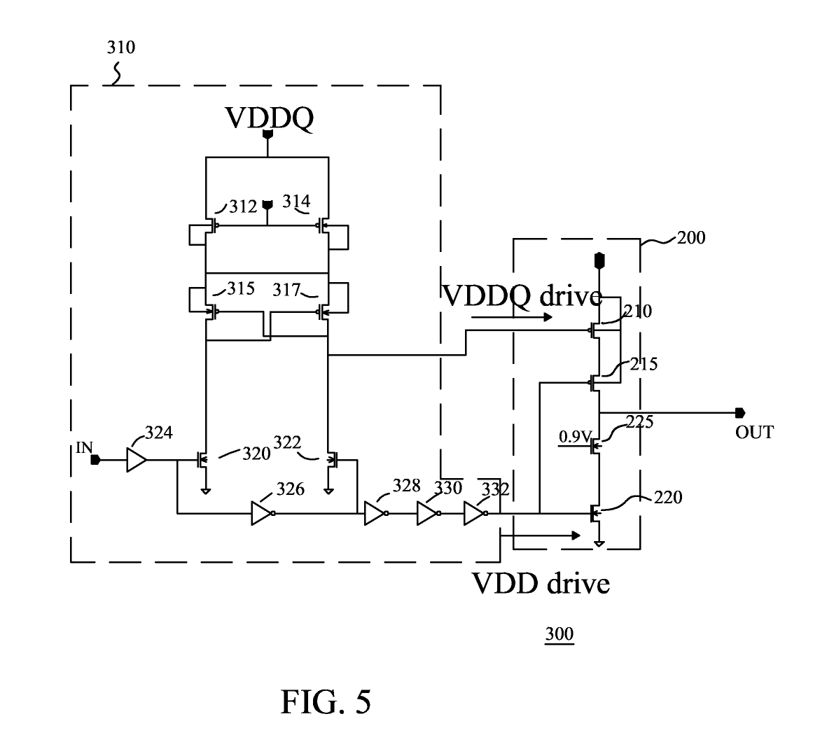

FIG. 5 is a schematic diagram illustrating a word-line driver 300 employing the high voltage tolerative CMOS inverter 200 of FIG. 3. The word-line driver 300 includes a voltage-down converter 310 to provide the different voltages at the gates of PMOS transistors 210, 215 and NMOS transistor 220. PMOS transistors 312, 314, 315 and 317 can operate at the high voltage VDDQ. The cascoded PMOS transistors 312 and 315 drop the voltage for a NMOS transistor 320. Similarly the cascoded PMOS transistors 314 and 317 drop the voltage for a NMOS transistor 322. The NMOS transistors 320 and 322 as well as inverters 324, 326, 328, 330 and 332 are operated at a relatively lower voltage supply, VDD (not shown). A word-line selection signal from a decoder can be the input to inverter 324. The voltages at the gates of the transistors of the CMOS inverter 200 are synchronized, i.e., when the gate of PMOS 210 is high, the gates of NMOS 220 and PMOS 215 are high, too, and vice versa, but the gate of PMOS 210 is significantly higher than the gates of NMOS 220 and PMOS 215 when both are at higher voltage. The circuit 310 is only one example of a voltage down converter, and a skilled artisan would be able to construct such circuit of different structure.

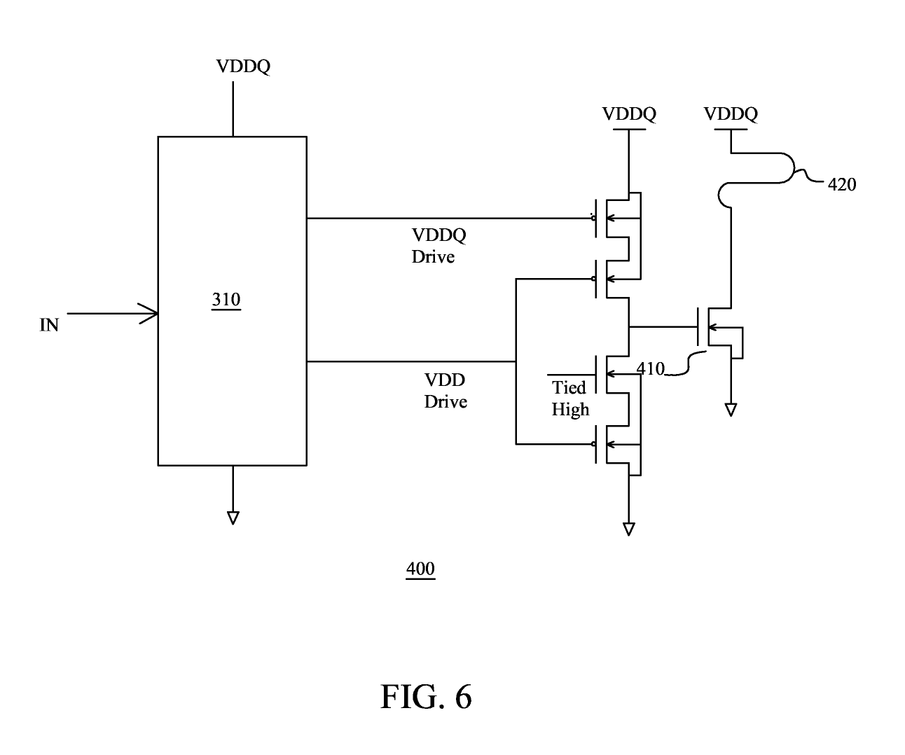

FIG. 6 is a schematic diagram illustrating a fuse module 400 employing the high voltage tolerative CMOS inverter of FIG. 3. The high voltage tolerative CMOS inverter 200 outputs to the gate of a switching NMOS transistor 410. When the NMOS transistor 410 is turned on, a fuse 420 that is serially connected to the NMOS transistor 410 will be programmed. In a conventional CMOS inverter, during a power-on period, the PMOS transistor may be turned on for a very short period of time before the NMOS transistor is turned on. When the fuse module 400 is controlled by such conventional driver, the NMOS transistor 410 may be temporarily turned on during the power-on period, which may cause mis-programming of the fuse 420. However, when using the high voltage tolerative CMOS inverter 200 with separated control gate voltage controls, the NMOS transistor 220 can be turned on earlier due to a less voltage rise which prevents the inverter from generating a voltage spike. Therefore, the fuse module 400 will not suffer mis-programming issue.

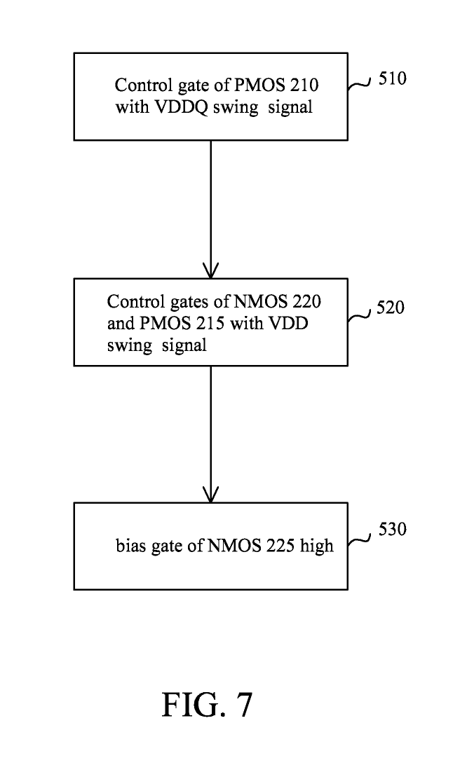

FIG. 7 illustrates a method of operating the high voltage tolerative CMOS inverter 200. At step 510, the gate of PMOS 210 is controlled with a first signal having a VDDQ swing. At step 520, the gates of NMOS 220 and PMOS 215 are controlled with a second signal having a VDD swing. VDD is lower than VDDQ, and the voltage swings between VDDQ and VSS by the first signal and between VDD and VSS by the second signal are synchronized in the same direction. At step 530, the gate of NMOS 225 is biased high.

As set forth above, a CMOS inverter-based driver makes use of two principles to protect its transistors from GOI. First, the input to PMOS and NMOS transistors is separated. Second, a stack of PMOS and NMOS transistors is used to reduce the voltage across each MOS. This design exhibits enhanced device reliability under high voltage stresses that can appear when a device is off.

In certain embodiments if a high voltage tolerative inverter circuit, the inverter circuit includes: a first PMOS transistor with a source connected to a first high voltage power supply (VDDQ) and drain connected to a first node; a second PMOS transistor with a source connected to the first node and a drain connected to an output terminal; a first NMOS transistor with a source connected to a low voltage power supply (VSS) and a drain connected to a second node; a second NMOS transistor with a source connected to the second node and a drain connected to the output terminal. A gate of the first PMOS transistor is controlled by a first signal having a voltage swing between VDDQ and VSS. A gate of the first NMOS transistor and the second PMOS transistor are controlled by a second signal having a voltage swing between a second high voltage power supply (VDD) and VSS. VDD is lower than VDDQ. In embodiments, the voltage swings between VDDQ and VSS by the first signal and between VDD and VSS by the second signal are synchronized in the same direction. A gate of the second NMOS transistor is biased with a first voltage greater than VSS. In some embodiments, an electrical fuse element is provided in serial connection with a switching device. A control terminal of the switching device is coupled to the output terminal of the inverter.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention.

What is claimed is:

1. A high voltage tolerative inverter circuit comprising:
a first PMOS transistor with a source connected to a first high voltage power supply (VDDQ) and drain connected to a first node;
a second PMOS transistor with a source connected to the first node and a drain connected to an output terminal;
a first NMOS transistor with a source connected to a low voltage power supply (VSS) and a drain connected to a second node;
a second NMOS transistor with a source connected to the second node and a drain connected to the output terminal;
a gate of the first PMOS transistor being controlled by a first signal having a voltage swing between VDDQ and VSS;
a gate of the first NMOS transistor and second PMOS transistor being controlled by a second signal having a voltage swing between a second high voltage power supply (VDD) and VSS, wherein VDD is lower than VDDQ; and
a gate of the second NMOS transistor being biased with a first voltage greater than VSS.

2. The high voltage tolerative inverter circuit of claim 1, wherein the first voltage is VDD.

3. The high voltage tolerative inverter circuit of claim 1, wherein the voltage swings between VDDQ and VSS by the first signal and between VDD and VSS by the second signal are synchronized in the same direction.

4. The high voltage tolerative inverter circuit of claim 3, wherein the voltage swings by the first and second signals are simultaneous.

5. The high voltage tolerative inverter circuit of claim 1, further comprising a voltage down converter supplying both the first and second signals.

6. The high voltage tolerative inverter circuit of claim 5, wherein the voltage down converter comprises at least two cascoded PMOS transistors and an NMOS transistor.

7. The high voltage tolerative inverter circuit of claim 1, further comprising an electrical fuse element in serial connection with a switching device, the switching device being controlled by the output of the high voltage tolerative inverter circuit.

8. The high voltage tolerative inverter circuit of claim 7, wherein the switching device is a NMOS transistor with a gate coupled to the output terminal of the high voltage tolerative inverter circuit.

9. A fuse control circuit comprising:
a first PMOS transistor with a source connected to a first high voltage power supply (VDDQ) and drain connected to a first node;
a second PMOS transistor with a source connected to the first node and a drain connected to an output terminal;
a first NMOS transistor with a source connected to a low voltage power supply (VSS) and a drain connected to a second node;
a second NMOS transistor with a source connected to the second node and a drain connected to the output terminal;
a gate of the first PMOS transistor being controlled by a first signal having a voltage swing between VDDQ and VSS;
a gate of the first NMOS transistor and second PMOS transistor being controlled by a second signal having a voltage swing between a second high voltage power supply (VDD) and VSS, wherein VDD is lower than VDDQ;
a gate of the second NMOS transistor being biased with a first voltage greater than VSS; and
an electrical fuse element in serial connection with a switching device, a control terminal of the switching device being coupled to the output terminal.

10. The high voltage tolerative inverter circuit of claim 9, wherein the first voltage is VDD.

11. The high voltage tolerative inverter circuit of claim 9, wherein the voltage swings between VDDQ and VSS by the first signal and between VDD and VSS by the second signal are synchronized in the same direction.

12. The high voltage tolerative inverter circuit of claim 11, wherein the voltage swings by the first and second signals are simultaneous.

13. The high voltage tolerative inverter circuit of claim 10, further comprising a voltage down converter supplying both the first and second signals.

14. The high voltage tolerative inverter circuit of claim 13, wherein the voltage down converter comprises at least two cascoded PMOS transistors and an NMOS transistor.

15. The high voltage tolerative inverter circuit of claim 9, wherein the switching device is a NMOS transistor with a gate coupled to the output terminal of the high voltage tolerative inverter circuit.

16. A method, comprising:
providing a high voltage tolerative inverter circuit, the inverter circuit comprising:
a first PMOS transistor with a source connected to a first high voltage power supply (VDDQ) and drain connected to a first node;
a second PMOS transistor with a source connected to the first node and a drain connected to an output terminal;
a first NMOS transistor with a source connected to a low voltage power supply (VSS) and a drain connected to a second node; and
a second NMOS transistor with a source connected to the second node and a drain connected to the output terminal;
controlling a gate of the first PMOS transistor with a first signal having a voltage swing between VDDQ and VSS,
controlling a gate of the first NMOS transistor and second PMOS transistor with a second signal having a voltage swing between a second high voltage power supply (VDD) and VSS, wherein VDD is lower than VDDQ; and
biasing a gate of the second NMOS transistor being with a first voltage greater than VSS,
wherein the voltage swings between VDDQ and VSS by the first signal and between VDD and VSS by the second signal are synchronized in the same direction.

17. The method of claim 16, wherein the first voltage is VDD.

18. The method of claim 16, further comprising the step of supplying both the first and second signals with a voltage down converter.

19. The method of claim 16, further comprising the step of providing an electrical fuse element in serial connection with a switching device, and controlling the switching device with an output of the high voltage tolerative inverter circuit.

20. The method of claim 19, wherein the switching device is a NMOS transistor with a gate coupled to the output terminal of the high voltage tolerative inverter circuit.
